(19) United States
(12) Patent Application Publication
(10) Pub. No.: US 2004/0197944 A1
(43) Pub. Date: Oct. 7, 2004

(54) Method of forming encapsulation structure for organic light-emitting device

(75) Inventors: Kuang-Jung Chen, Taipei (TW); Yaw-Ming Tsai, Taichung (TW)

Correspondence Address: BACON & THOMAS, PLLC, 625 SLATERS LANE, FOURTH FLOOR, ALEXANDRIA, VA, 22314

(73) Assignee: Toppoly Optoelectronics Corp., Miao-Li (TW)

(21) Appl. No.: 10/459,572

(22) Filed: Jun. 12, 2003

(30) Foreign Application Priority Data
Apr. 4, 2003 (TW) 092107799

(51) Int. Cl. H01L 21/00

(52) U.S. Cl. 438/26

(57) ABSTRACT

A method of forming an encapsulation structure for an organic light-emitting device is disclosed. The method is applied to organic light-emitting devices (OLED) and performed in a single reaction chamber. The method includes steps of placing an organic light-emitting device into a plasma chamber, forming a first buffer layer on the organic light-emitting device, forming a first passivation layer on the first buffer layer, forming a second buffer layer on the first passivation layer, and forming a second passivation layer on the second buffer layer.

### FIELD OF THE INVENTION

This invention relates to a method of forming an encapsulation structure for a multicolor organic electroluminescent display, and more particularly to a method of forming an encapsulation structure for an organic light-emitting device (OLED).

### BACKGROUND OF THE INVENTION

With the rapid developments of digital technologies, panel displays have become essential components for many electrical appliances such as notebooks, mobile phones, information appliances (IA) and personal digital assistants (PDA). Generally speaking, lightness, thinness and/or low electricity consumption are basic requirements of typical panel displays. However, depending on viewing angles, brightness, high image quality and stability on temperature, related arts are required to be further developed. An organic light-emitting device (OLED) has been developed as a new technology for the next generation of panel displays due to its properties of self-light-emitting (without using a backlight), wider viewing angle, rapid response, simple manufacturing process and low energy consumption.

It is only quite recently to develop the technologies of the organic light-emitting device (OLED) so that the related technologies of the organic light-emitting device (OLED) still have some problems to be solved. In particular, the moisture and the oxygen in the atmosphere always cause the cathode of the organic light-emitting device to be oxidized and the interface of the organic compound of the organic light-emitting device to peel off easily. Such phenomenon may cause the organic electroluminescent display to form dark spots, reduce the yield and luminance of the organic electroluminescent display, and shorten the use life of the organic electroluminescent display. In order to prevent the above-mentioned problems from happening, the traditional technology employs a metal-sealing container or glass-sealing container to seal and protect the organic light-emitting device so as to avoid the materials of the electrode layer and the organic layer contacting with the external environment.

However, the metal-sealing container is heavy and has the shortcomings of being oxidized easily during the manufacturing process, and the glass-sealing container is brittle, heavy and not easy to process. On the other hand, both the metal and glass materials are hard to adhere to the organic light-emitting device and the adhesive area of the organic light-emitting device isn't smooth enough. Therefore, the encapsulation structure of the organic light-emitting device is subject to peel off. Moreover, there is a tendency to replace the glass material of the substrate with plastic material so that the metal-sealing container and glass-sealing container will be discarded in the future. In order to promote the organic light-emitting device to be lighter and thinner, and fit in with the tendency of entirely plasticizing the organic light-emitting device in the future, the compact encapsulation and protection structure produced by means of plating should be positively strengthened and further researched.

Please refer to FIG. 1, which shows a cross-section view of an encapsulation structure for a conventional organic light-emitting device. As shown in FIG. 1, the organic light-emitting device 10 generally includes a substrate 101, a first conductive layer 102, an organic light-emitting multilayer structure 103 and a second conductive layer 104. The substrate 101 is a glass substrate or a metal substrate, and the first conductive layer 102 is an indium tin oxide (ITO) film or an indium zinc oxide (IZO) film. The second conductive layer 104 is one selected from a group consisting of a metal film, a metal compound film, an indium tin oxide (ITO) film and an indium zinc oxide (IZO) film. In order to avoid the electrode layer and the organic layer of the organic light-emitting device contacting with the external environment, there should be an encapsulation or protection structure 11 formed on the organic light-emitting device 10. The traditional and essential encapsulating steps for the organic light-emitting device 10 are described as the following.

First, the polymer material, such as the polymer precursor of methacrylate, is plated on the organic light-emitting device 10 via a thermo-sublimation method. The polymer material is polymerized to form the first buffer layer 111 by means of light illumination. Then, an inorganic or a ceramic material is employed to form the first passivation layer 112 on the first buffer layer 111 by means of sputtering or chemical vapor deposition (CVD) in the reaction chamber. Thereafter, the substrate 101 is delivered to the polymer-deposition chamber to form the second buffer layer 113 on the first passivation layer 112. Finally, the entire substrate 101 is delivered to the reaction chamber of the inorganic or ceramic material for forming the second passivation layer 114 on the second buffer layer 113. The material layers of the encapsulation structure 11 could be produced by means of repeating the above-mentioned steps according to the requirements.

During the process of forming the encapsulation structure 11, the entire substrate 101 must be delivered repeatedly between the polymer-deposition reaction chamber and the thermo-sublimation chamber for forming the buffer layers and the passivation layers respectively. Such repeating process is complex. Furthermore, it is also important to consider whether the light would influence the organic material of the device when the organic light-emitting device is a top emission type organic light-emitting device.

Therefore, it is desired to provide an encapsulation structure for an organic light-emitting device, which is capable of being produced easily, efficiently and at low cost, and can rectify those drawbacks of the prior art and solve the above-encountered problems.

### SUMMARY OF THE INVENTION

It is therefore an object of the present invention to provide a method of forming an encapsulation structure for an organic light-emitting device, which is performed in a single chamber and capable of being applied to the organic light-emitting device with glass substrates, metal substrates and plastic substrates. Thereby, the encapsulation structure of the organic light-emitting device is lighter, thinner and fine-confluence, and the use life of the organic light-emitting device is increased.

To achieve the above-mentioned objects of the present invention, a method of forming an encapsulation structure for an organic light-emitting device is provided. The method includes steps of placing an organic light-emitting device into a plasma chamber, forming a first buffer layer on the organic light-emitting device by means of PECVD without exposing the polymer precursor to be solidified, forming a first passivation layer on the first buffer layer, forming a second buffer layer on the first passivation layer, and forming a second passivation layer on the second buffer layer, wherein the first buffer layer, the first passivation layer, the second buffer layer and the second passivation layer are formed via a process of plasma polymerization performed in a single plasma reaction chamber.

In an embodiment, the plasma polymerization process can be a process of plasma enhanced chemical vapor deposition (PECVD), high-density plasma chemical vapor deposition (HDPCVD) or inductively coupled plasma chemical vapor deposition (ICPCVD). In addition, the method further includes a step of surface treatment or a step of self-clean with the organic light-emitting device for demand while forming the buffer layers and the passivation layers. Preferably, the first passivation layer and the second passivation layer are made of diamond-like carbon materials. More preferably, the first buffer layer and the second buffer layer are formed by a polymer film made of a polymer precursor, which is one selected from a group consisting of styrene, acetylene, ethylene, methylbenzene and octafluorocyclobutane (C₄F₈).

In accordance with one aspect of the present invention, the organic light-emitting device could be a passive matrix organic light-emitting device or an active matrix organic light-emitting device capable of emitting light downwardly or upwardly. Preferably, the substrate is a glass substrate or a plastic substrate.

In accordance with another aspect of the present invention, the organic light-emitting device includes a substrate, a first conductive layer formed on the substrate, an organic light-emitting multilayer structure formed on the first conductive layer, and a second conductive layer formed on the organic light-emitting multilayer structure.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 shows a cross-section view of an encapsulation structure for a conventional organic light-emitting device; and

FIGS. 2(a)-2(d) are the cross-sectional views showing the flow process of forming an encapsulation structure for an organic light-emitting device according to a preferred embodiment of the present invention.

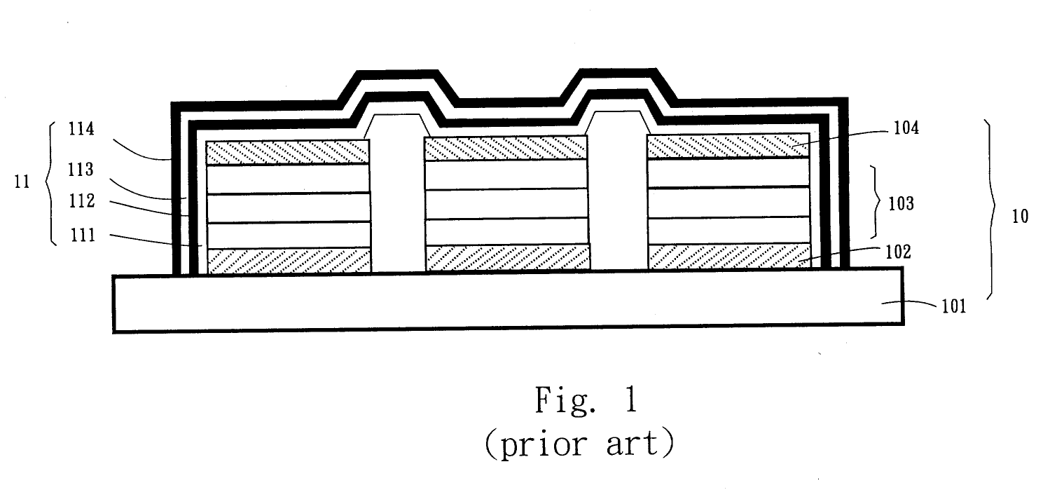

### DETAILED DESCRIPTION OF THE PREFERRED EMBODIMENT

The present invention discloses a method of forming an encapsulation structure for an organic light-emitting device. The organic light-emitting device is roughly divided into passive matrix type and the active matrix type. For describing the main technology of the present invention clearly, a passive matrix organic light-emitting device is introduced as an embodiment in the following descriptions. It is to be noted that the present invention needn't be limited to the passive matrix organic light-emitting device. On the contrary, other kinds of organic light-emitting devices, such as an active matrix organic light-emitting device capable of emitting light upwardly or downwardly, are also cooperated herewith for reference. In addition, the substrate of the organic light-emitting device needn't to be limited to glass substrate. The metal substrate and the plastic substrate are also cooperated herewith for reference.

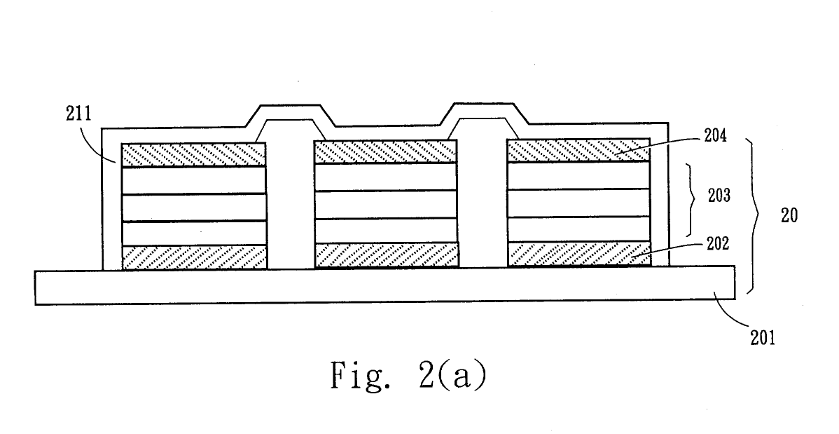

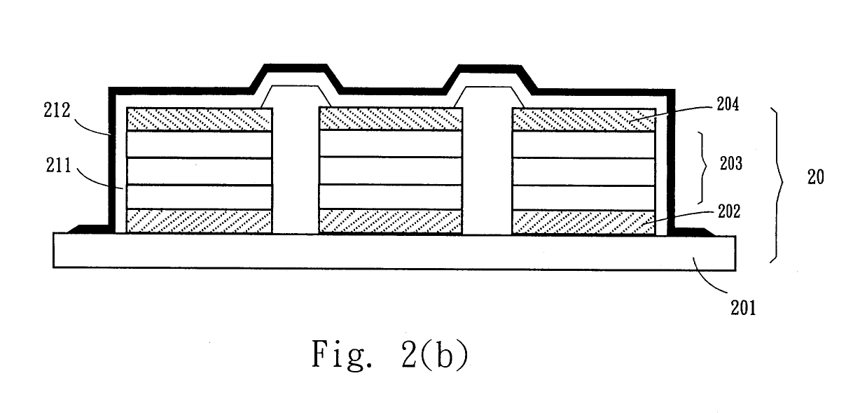

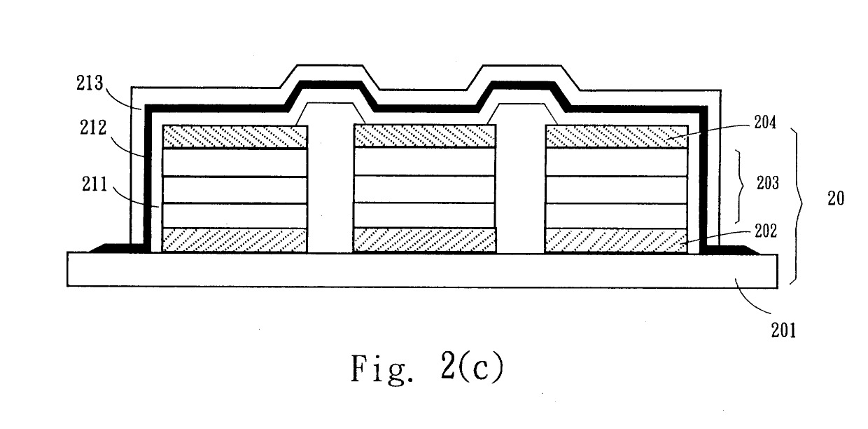

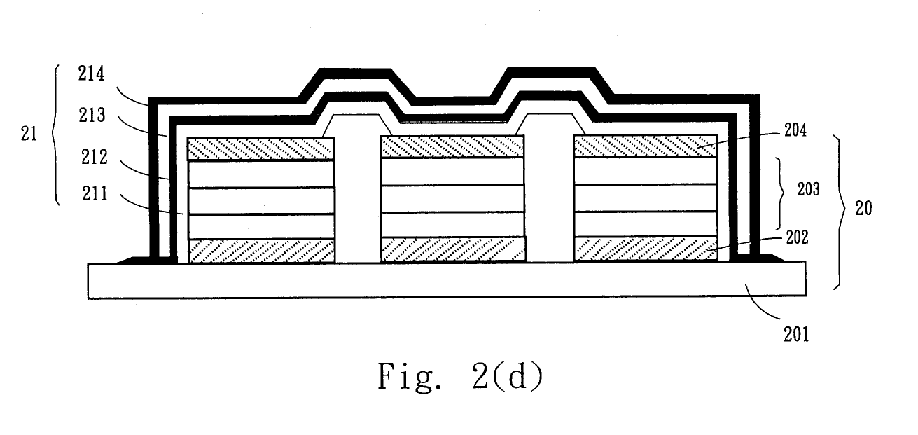

Please refer to FIGS. 2(a)-2(d), which are the cross-sectional views showing the flow process of forming an encapsulation structure for an organic light-emitting device according to a preferred embodiment of the present invention. As shown in FIG. 2(a), firstly, a passive matrix organic light-emitting device 20 with a substrate 201, a first conductive layer 202, an organic light-emitting device 203 and a second conductive layer 204 is placed in a plasma chamber (not shown), and a first buffer layer 211 is formed on the organic light-emitting device 20. In FIG. 2(b), a passivation layer 212 is formed on the first buffer layer 211 by means of plasma polymerization process. Then, as shown in FIG. 2(c), a second buffer 213 is formed on the first passivation layer 212 via plasma polymerization process performed in the same plasma reaction chamber. Thereafter, as shown in FIG. 2(d), a second passivation layer 214 is formed via plasma polymerization process performed in the same plasma reaction chamber. The steps of forming buffer layers and passivation layers can be repeated according to the requirements. If a pattern is required, a shadow mask can be employed to cover the portion free from plating. Accordingly, the entire encapsulation structure is completed.

During the process of forming the encapsulation structure 21 for the organic light-emitting device, the plasma polymerization process is plasma enhanced chemical vapor deposition (PECVD) performed with a reaction gas containing methane (CH₄), methylbenzene (C₆H₅CH₃) or octafluorocyclobutane (C₄F₈). In the plasma reaction chamber, both the first passivation layer 212 and the second passivation layer 214 are made of diamond-like carbon material. Moreover, some metal materials, such as titanium (Ti), niobium (Nb), tantalum (Ta), chromium (Cr), molybdenum (Mo), tungsten (W), ruthenium (Ru), iron (Fe), cobalt (Co), nickel (Ni), aluminum (Al), copper (Cu), gold (Au), or silver (Ag) or some nonmetal materials, for example silicon (Si) or III-V group elements, can be selectively doped for adjusting the parameters of the process according to the requirements. In addition to the plasma enhanced chemical vapor deposition (PECVD) process, high-density plasma chemical vapor deposition (HDPCVD) process, inductively coupled plasma chemical vapor deposition (ICPCVD) or other plasma polymerization process can also be applied in the present invention. Furthermore, the first buffer layer 211 and the second buffer layer 213 are formed in the same reaction chamber performed with a reaction gas containing a polymer precursor. The polymer precursor can be selected from a group consisting of styrene, acetylene, ethylene, methylbenzene and octafluorocyclobutane (C₄F₈), and will form a polymer film of a polymer precursor, such as a polymer diamond-like carbon film, so as to form the first buffer layer 211, the second buffer layer 213, the first passivation layer 212 and the second passivation layer 214 in a signal plasma reaction chamber. Certainly, an additional buffer layer (not shown) can be further formed on the second passivation layer 214, if necessary. After that, an additional passivation layer (not shown) can also be formed to prevent the organic light-emitting device from contacting the external environment.

The present invention employs the plasma polymerization process to sequentially form the first conductive layer 211, the first passivation layer 212, the second buffer layer 213 and the second passivation layer 214 on the organic light-emitting device 20 in a single plasma reaction chamber. So the drawbacks of forming the encapsulation structure by means of delivering the organic light-emitting device among different reaction chambers will be solved. For increasing the surface cleanliness and smooth level of the encapsulation structure, a step of self-clean and surface treatment with the organic light-emitting device could be introduced in the reaction chamber before performing the plasma polymerization process. Thereby, the surface cleanliness of the encapsulation structure is ensured.

Because the encapsulation structure 21 is used to completely isolate the organic layer and the conductive layer of the organic light-emitting device 20 from the external environment and to effectively dissipate the heat produced by the organic light-emitting device operated over a long period of time, the materials with high confluence and good thermal conductivity are the best choice for the encapsulation structure. Comparing the diamond-like carbon (DLC) materials of the present invention with the traditional organic materials or ceramic materials, the DLC materials are excellent in anti-friction and thermally conductive, and simultaneously has a feature of low water penetration. In addition, the DLC materials could form a polymer DLC film with low hardness or an amorphous DLC film with high hardness according to the manufacturing methods, the doped materials and the parameters of the manufacturing process. Moreover, the color of the DLC film could be adjusted from brown to transparent. Hence, the encapsulation structure formed by the DLC materials can effectively prevent the organic light-emitting device from contacting with the external environment. Additionally, the second passivation layer 214 covering around the entire encapsulation structure will increase the wear-resistance of the organic light-emitting device and the use life of the organic light-emitting device.

In conclusion, the present invention provides a method of forming an encapsulation structure for an organic light-emitting device. The method of the present invention employs the plasma polymerization process and the diamond-like carbon materials to form the passivation layers, and introduces the plasma polymerization process and the polymer precursor to form the buffer layers, thereby forming the encapsulation structure in single plasma reaction chamber. The buffer layers are used for absorbing the stress formed between the first passivation layer and the second passivation layer. The method of the present invention can solve the drawbacks of the prior encapsulation structure formed by means of delivering the organic light-emitting device among different reaction chambers, simplifies the manufacturing process, decrease the manufacturing cost, and effectively prevent the organic light-emitting device from contacting the external environment.

Furthermore, the encapsulation structure with the diamond-like carbon materials is highly compact, excellent at thermal conductance wear-resisting, high hardness and corrosion-resisting so as to fit in with the demand of the organic light-emitting device. Accordingly, the present invention possesses many outstanding characteristics, effectively improves upon the drawbacks associated with the prior art in practice and application, produces practical and reliable products, bears novelty, and adds to economical utility value. Therefore, the present invention exhibits a great industrial value.

While the invention has been described in terms of what is presently considered to be the most practical and preferred embodiments, it is to be understood that the invention need not be limited to the disclosed embodiment. On the contrary, it is intended to cover various modifications and similar arrangements included within the spirit and scope of the appended claims, which are to be accorded with the broadest interpretation so as to encompass all such modifications and similar structures.

1. A method of forming an encapsulation structure for an organic light-emitting device, comprising the steps of:
placing said organic light-emitting device into a single plasma chamber;
forming a first buffer layer directly on said organic light-emitting device;
forming a first passivation layer on said first buffer layer;
forming a second buffer layer on said first passivation layer; and
forming a second passivation layer on said second buffer layer,
wherein said first buffer layer said first passivation layer said second buffer layer and said second passivation layer are formed in said single plasma chamber.

2. The method according to claim 1 wherein said first buffer layer, said first passivation layer, said second buffer layer, and said second passivation layer are formed in an adjustable and repeatable sequence.

3. The method according to claim 1 wherein said first buffer layer, said first passivation layer, said second buffer layer and said second passivation layer are formed via a plasma polymerization process.

4. The method according to claim 3 wherein said plasma polymerization process is plasma enhanced chemical vapor deposition (PECVD) process.

5. The method according to claim 3 wherein said plasma polymerization process is a high-density plasma chemical vapor deposition (HDPCVD) process.

6. The method according to claim 3 wherein said plasma polymerization process is inductively coupled plasma chemical vapor deposition (ICPCVD) process.

7. The method according to claim 1 further comprising a step of surface treatment with said organic light-emitting device.

8. The method according to claim 1 further comprising a step of self-cleaning with said organic light-emitting device.

9. The method according to claim 1 wherein said first passivation layer and said second passivation layer are made of diamond-like carbon materials.

10. The method according to claim 1 wherein said first buffer layer and said second buffer layer are formed by a polymer film made of a polymer precursor.

11. The method according to claim 10 wherein said polymer precursor is one selected from a group consisting of styrene, acetylene, ethylene, methylbenzene and octafluorocyclobutane (C₄H₈).

12. The method according to claim 1 wherein said organic light-emitting device is a passive matrix organic light-emitting device.

13. The method according to claim 1 wherein said organic light-emitting device is an active matrix organic light-emitting device.

14. The method according to claim 13 wherein said active matrix organic light-emitting device emits light downwardly.

15. The method according to claim 13 wherein said active matrix organic light-emitting device emits light upwardly.

16. The method according to claim 1 wherein said organic light-emitting device comprises:
a substrate;
a first conductive layer formed on said substrate;
an organic light-emitting multilayer structure formed on said first conductive layer; and
a second conductive layer formed on said organic light-emitting multilayer structure.

17. The method according to claim 16 wherein said substrate is a glass substrate.

18. The method according to claim 16 wherein said substrate is a plastic substrate.
